(19) United States
(12) Patent Application Publication
(10) Pub. No.: US 2026/0190760 A1
(43) Pub. Date: Jul. 2, 2026

(54) Light Emitting Display Device

(71) Applicant: LG Display Co., Ltd., Seoul (KR)

(72) Inventors: Dong Il Choi, Paju-si (KR); Seung Kwang Roh, Paju-si (KR); Woo Chul Choi, Paju-si (KR); Sang Kyoung Moon, Paju-si (KR); Jung Mo Cho, Paju-si (KR); Chi Hak Lee, Paju-si (KR); Bo A Jin, Paju-si (KR); Min Gue Shin, Paju-si (KR)

(21) Appl. No.: 19/430,924

(22) Filed: Dec. 23, 2025

(30) Foreign Application Priority Data
Dec. 31, 2024 (KR) 10-2024-0202817

(51) Int. Cl. H10K 59/80; H10K 59/122; H10K 102/00

(52) U.S. Cl. CPC H10K 59/80521; H10K 59/122; H10K 59/87; H10K 2102/351

(57) ABSTRACT

Disclosed is a light emitting display device including a plurality of light emitting portions spaced from each other and a non-light emitting portion between the light emitting portions, a light emitting diode provided on the substrate such that the light emitting diode overlaps with each of the light emitting portions, a first capping layer and a pattern-defining layer disposed on the light emitting diode in the light emitting portions, a pattern electrode disposed adjacent to a side surface of the first capping layer in the non-light emitting portion, and a second capping layer covering the pattern electrode and the pattern-defining layer.

### CROSS-REFERENCE TO RELATED APPLICATIONS

This application claims priority under 35 U.S.C. § 119 (a) to the Republic of Korea Patent Application No. 10-2024-0202817, filed on Dec. 31, 2024, the entire contents of which are hereby expressly incorporated by reference into the present application.

### TECHNICAL FIELD

The present disclosure relates to a light emitting display device that reduces resistance unevenness between common electrode regions and improves frontal luminous efficacy.

### BACKGROUND

With the advent of the information society, there is increasing demand for various forms of display devices for displaying images.

A light emitting display device that includes light emitting diodes to constitute pixels does not require a separate light source unit and is thus advantageous for slimness or flexibility and has excellent color purity.

For example, a light emitting diode includes two different electrodes and a light emitting layer between the electrodes, wherein, when electrons generated from one electrode and holes generated from the other electrode are injected into the light emitting layer, the holes recombine with the electrons to form excitons, and the excitons fall from an excited state to a ground state, thereby resulting in light emission.

### SUMMARY

Accordingly, the present disclosure is directed to a light emitting display device that substantially obviates one or more problems due to limitations and disadvantages of the related art.

One object of the present disclosure is to provide a light emitting display device that is capable of solving the resistance unevenness between the areas of the common electrode formed in common to subpixels in a large area configuration.

Another object of the present disclosure is to provide a light emitting display device that is capable of improving the adhesion of the pattern electrode.

Another object of the present disclosure is to provide a light emitting display device that is capable of maximizing luminous efficacy.

Another object of the present disclosure is to provide a light emitting display device that is capable of obtaining stable and improved image quality.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a light emitting display device includes a plurality of light emitting portions spaced from each other and a non-light emitting portion between the light emitting portions, a light emitting diode provided on the substrate such that the light emitting diode overlaps with each of the light emitting portions, a first capping layer and a pattern-defining layer disposed on the light emitting diode in the light emitting portions, a pattern electrode disposed adjacent to a side surface of the first capping layer in the non-light emitting portion, and a second capping layer covering the pattern electrode and the pattern-defining layer.

It is to be understood that both the foregoing general description and the following detailed description of the present disclosure are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a plan view illustrating a light emitting display device according to an embodiment of the present disclosure.

FIG. 2 is a circuit diagram illustrating a subpixel including each light emitting portion of FIG. 1.

FIG. 3 is a cross-sectional view taken along line I-I′ of FIG. 1.

FIG. 4A is a plan view illustrating a common electrode of FIG. 3.

FIG. 4B is a plan view illustrating a first capping layer and a pattern-defining layer of FIG. 3.

FIG. 4C is a plan view illustrating a pattern electrode of FIG. 3.

FIG. 5 is a cross-sectional view taken along line II-II′ of FIG. 1.

FIG. 6 is a graph showing a refractive index and an absorption rate of the pattern-defining layer.

FIG. 7 is a plan view illustrating a unit pixel of a light emitting display device according to another embodiment of the present disclosure.

FIG. 8A is a plan view illustrating a first capping layer and a pattern-defining layer of the unit pixel of FIG. 7.

FIG. 8B is a plan view illustrating a pattern electrode of the unit pixel of FIG. 7.

### DETAILED DESCRIPTION

Hereinafter, embodiments according to the present disclosure will be described in detail with reference to the attached drawings. Reference will now be made in detail to example embodiments of the present disclosure, examples of which are illustrated in the accompanying drawings. Wherever possible, the same reference numbers will be used throughout the drawings to refer to the same or like parts, unless otherwise specified. Further, for convenience of description, a scale in which each of elements is illustrated in the accompanying drawings can differ from an actual scale. Thus, the illustrated elements are not limited to the specific scale in which they are illustrated in the drawings.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations may be omitted. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, the light emitting display device according to the present disclosure will be described with reference to the attached drawings.

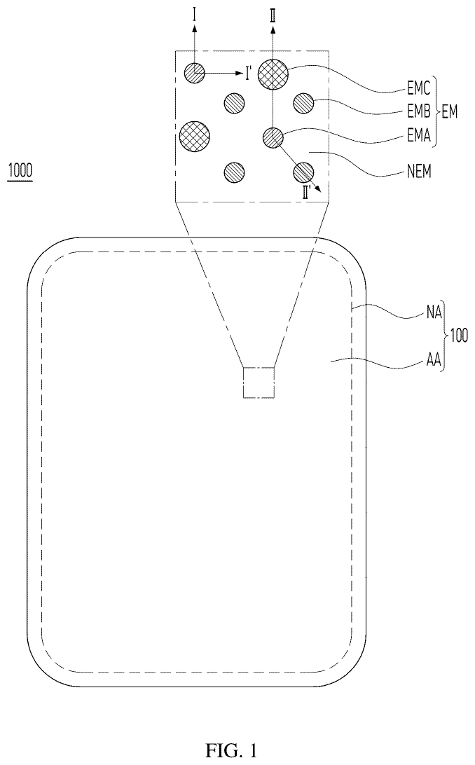

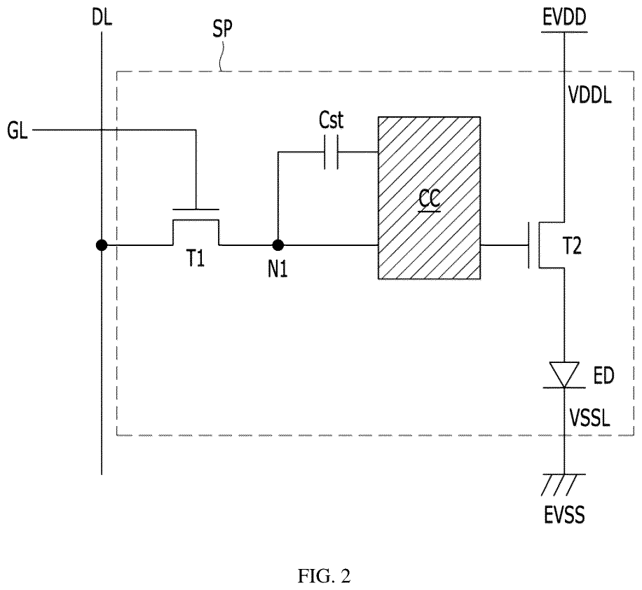

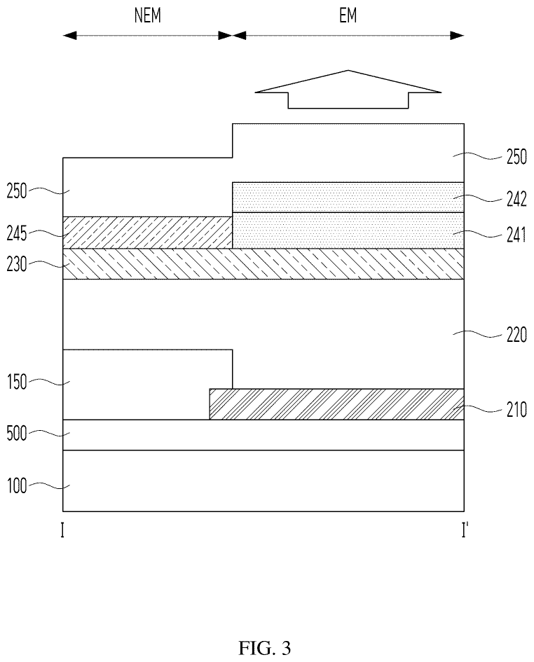

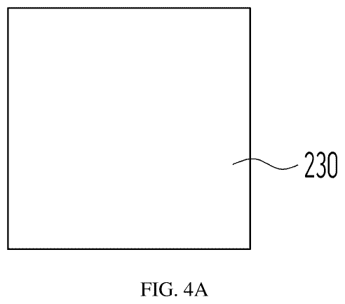

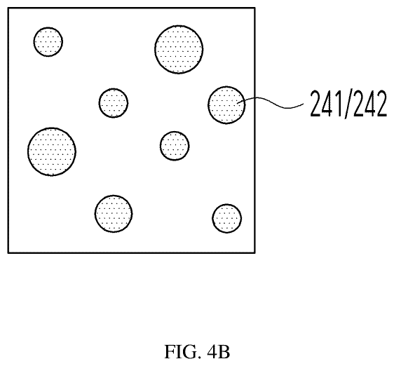

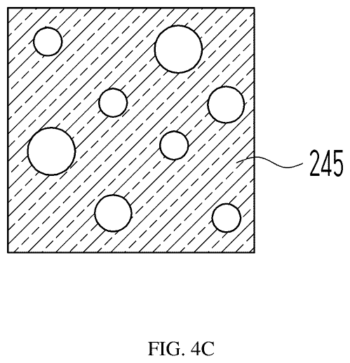

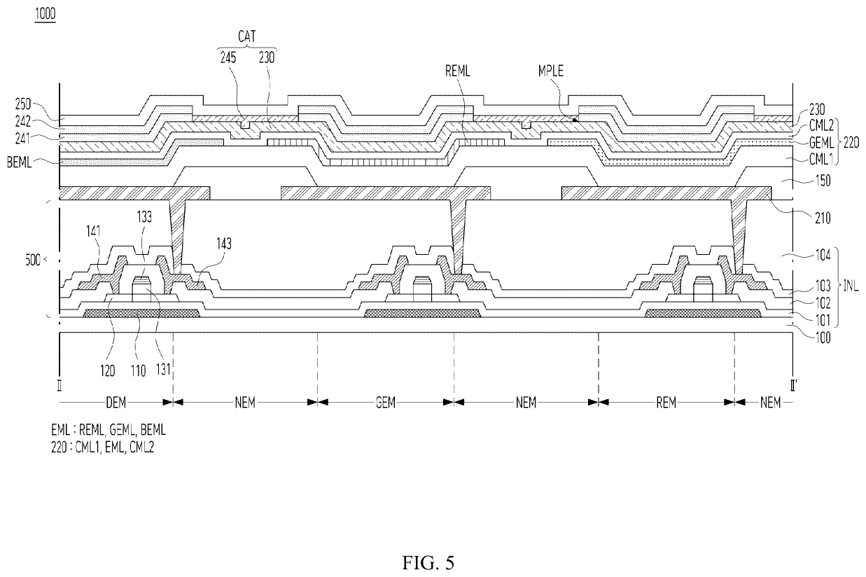

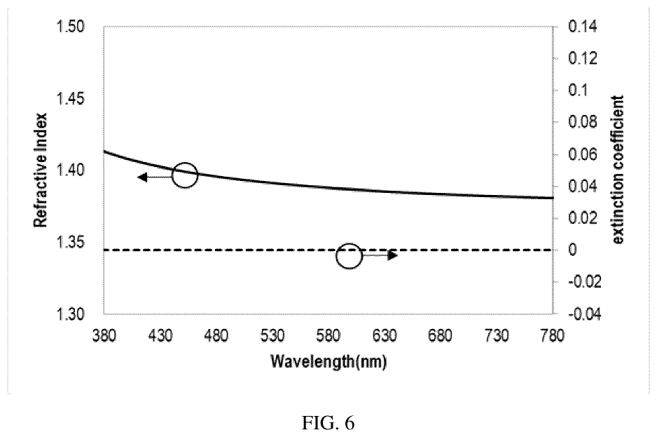

FIG. 1 is a plan view illustrating a light emitting display device according to an embodiment of the present disclosure. FIG. 2 is a circuit diagram illustrating a subpixel including each light emitting portion of FIG. 1. FIG. 3 is a cross-sectional view taken along line I to I′ of FIG. 1. FIG. 4A is a plan view illustrating a common electrode of FIG. 3. FIG. 4B is a plan view illustrating a first capping layer and a pattern-defining layer of FIG. 3. FIG. 4C is a plan view illustrating a pattern electrode of FIG. 3. FIG. 5 is a cross-sectional view taken along line II to II′ of FIG. 1. FIG. 6 is a graph showing a refractive index and an absorption rate of the pattern-defining layer.

As shown in FIG. 1, the light emitting display device 1000 according to an embodiment of the present disclosure includes a substrate 100 divided into a display area AA and a non-display area NA.

The display area AA of the substrate 100 includes subpixels SP to display an image. The non-display area NA is disposed around the display area AA, and a driving unit and a bezel may be disposed. The non-display area NA may include pad electrodes that receive signals from the driving unit at the outermost extended portions of the gate lines GL and data lines DL disposed in the display area AA. The pad electrodes may be connected to the driving unit.

Here, the display area AA is referred to as an active area and the non-display area NA is also referred to as a non-active area.

The display area AA includes a plurality of subpixels SP, as shown in FIGS. 1 to 3.

The substrate 100 may include a plurality of gate lines GL and a plurality of data lines DL, and may include a subpixel SP disposed at each of the intersections of a plurality of gate lines GL and a plurality of data lines DL. The structure of the subpixel SP may vary depending on the type of the light emitting display device 1000.

In the non-display area NA, the driving unit may include, for example, a scan driver that supplies a scan signal to drive a gate line GL provided in the display area AA, and a data driver that transmits a data signal to the data line DL. In addition, the driving unit may include an image processor, a timing controller, and a power supply to control the generation and supply of the scan signal and the data signal. The image processor, the timing controller, and the power supply may be disposed on a separate circuit board and connected to the substrate 100.

The display area AA displays an image in response to a data signal supplied from the data driver, a scan signal supplied from the scan driver, and power supplied from the power supply.

For example, the subpixels SP may be formed in a top emission method, a bottom emission method, or a dual emission method depending on the structure. The subpixels SP are units that may emit light of their own color with or without a specific type of color filter. For example, the subpixels SP may include a red subpixel, a green subpixel, and a blue subpixel. Alternatively, the subpixel SP may include, for example, a white subpixel in addition to the red subpixel, the green subpixel and the blue subpixel.

Each subpixel SP may include light emitting portions EM (EMA, EMB and EMC) where light is emitted, and a non-light emitting portion NEM surrounding the light emitting portions and overlapping with the bank 150. The subpixels SP may have areas of one or more different light emitting portions depending on light emitting characteristics. In the example shown at the top in FIG. 1, the area of the third light emitting portion EMC is larger than that of the first and second light emitting portions EMA and EMB.

For example, the first light emitting portion EMA may be the red light emitting portion REM of FIG. 5, the second light emitting portion EMB may be the green light emitting portion GEM of FIG. 5, and the third light emitting portion EMC may be the blue light emitting portion BEM of FIG. 5. Referring to FIG. 5, the red light emitting portion REM emits red light, the green light emitting portion GEM emits green light, and the blue light emitting portion BEM emits blue light.

The red light emitting portion REM includes a red light emitting layer REML, the green light emitting portion GEM includes a green light emitting layer GEML, and the blue light emitting portion BEM includes a blue light emitting layer BEML.

As shown in FIG. 1, when the blue luminous efficacy is low, the area of the blue light emitting portion can be relatively large, but the embodiment of the present disclosure is not limited thereto.

In addition, although the shape of the light emitting portion shown in FIG. 1 is depicted as a circle, this is provided as an example and the light emitting portion may have an elliptical, polygonal, or polygonal shape with multiple sides, and at least some corners of the polygon may be rounded.

The light emitting portion EM (EMA, EMB, EMC) may be defined as an open area of the bank 150, i.e., an opening. Referring to FIG. 3, the bank 150 may cover the edge of the first electrode 210 and expose the light emitting portion of the first electrode 210 of the substrate.

The light emitting portions EM (EMA, EMB, EMC) that emit different colors may be distinguished by, for example, different color emitting layers (REML, GEML, BEML) included in each area.

The non-display area NA may be disposed in an edge area surrounding the display area AA that displays the image. At least one driver for driving a plurality of subpixels SP may be disposed in the non-display area NA. The driver may be a gate-in-panel GIP provided together in the same stack as the configuration of the transistors T1 and T2 present in the subpixel. The gate driver may be disposed in the non-display area NA in the form of a gate-in-panel GIP and is connected to a plurality of gate lines GL of the display area AA, and may sequentially supply gate voltage signals to the plurality of gate lines GL.

Various additional elements may be further disposed in the non-display area NA to drive the subpixels SP in the display area AA.

Among the pixels, at least one sub-pixel SP includes a first transistor T1, a second transistor T2, a capacitor Cst, a compensation circuit CC, and an organic light emitting diode ED, as shown in FIG. 2.

For example, the first transistor T1 may be a switching transistor and the second transistor T2 may be a driving transistor.

The first electrode (e.g., drain electrode) of the first transistor T1 is electrically connected to the data line DL, and the second electrode (e.g., source electrode) is electrically connected to the first node N1. The gate electrode of the first transistor T1 is electrically connected to the gate line GL. The first transistor T1 transmits the data signal supplied through the data line DL to the first node N1 in response to the scan signal supplied through the gate line GL.

The storage capacitor Cst is electrically connected to the first node N1 and is charged by the voltage applied to the first node N1.

The first electrode (e.g., drain electrode) of the second transistor T2 receives a high potential driving voltage (EVDD), and the second electrode (e.g., source electrode) is electrically connected to a first electrode (e.g., an anode). The second transistor T2 may control the amount of driving current flowing through the organic light emitting diode ED in response to the voltage applied to the gate electrode.

The semiconductor layer of the first transistor T1 and/or the second transistor T2 may contain silicon such as amorphous silicon (a-Si), polycrystalline silicon (poly-Si), or low-temperature polycrystalline silicon (poly-Si), or may contain an oxide semiconductor, but is not limited thereto.

The transistor and display device of the embodiments of the present disclosure may include an oxide semiconductor layer in at least one of the transistors formed on the substrate 111, thus having the advantages of enabling formation at a relatively low temperature compared to other semiconductor materials, and having stable off characteristics and high mobility during operation.

The light emitting diode ED outputs light corresponding to the driving current. The light emitting diode ED has one side connected to a second transistor T2 and the other side connected to a first power supply voltage line VSSL supplied with a ground voltage or a low-potential driving (common) voltage EVSS, and may output light with one color of red, green, blue, and white in each sub-pixel.

The light emitting diode ED may include a first electrode, an intermediate layer disposed on the first electrode, and a second electrode. The intermediate layer may include at least one light emitting layer and may be implemented to emit light of the same color for the respective subpixels, such as white light, or may be implemented to emit different colors for respective subpixels SP, such as red, green, or blue light, when an electric field is formed between the first electrode and the second electrode. In addition to the light emitting layer, the intermediate layer may include various types of common layers and functional layers to efficiently supply holes and electrons to the light emitting layer. The second electrode may be directly or indirectly connected to a first power supply voltage line VSSL to which a low-potential driving voltage EVSS or a ground voltage is supplied. The first power supply voltage line to which the low-potential driving voltage EVSS or the ground voltage is supplied may be provided in a non-display area NA and may be further provided to be connected to at least one sub-pixel SP in a display area AA. A second transistor T2 that supplies driving current is connected to a second power supply voltage line VDDL on a side thereof not connected to the light emitting diode ED and thus receive a high-potential driving voltage EVDD.

The compensation circuit CC may be further provided in the subpixel SP to compensate for the threshold voltage of the second transistor T2. The compensation circuit CC may include one or more transistors. The compensation circuit CC may include at least one transistor and capacitor, and may be configured in various configurations depending on the compensation method. The subpixel SP including the compensation circuit CC may have various circuits with a variety of structures including transistors such as 3T1C, 4T2C, 5T2C, 6T1C, 6T2C, 7T1C, and 7T2C, or various numbers of transistors.

Among the transistors provided in the subpixels, the switching transistor may require high-speed driving to implement fast switching. The driving transistor may require high current output to provide high brightness by supplying high current to the light emitting diode.

Meanwhile, since the light emitting display devices according to embodiments of the present disclosure are provided with a second electrode in common for the subpixels SP of the display area AA and thus need to be disposed as a very thin film for light emission, when the low-potential driving voltage EVSS is applied to the second electrode only to a part of the non-display area NA, the common voltage within the display area AA may be changed due to an increase in the resistance of the second electrode within the display area AA, resulting in uneven brightness between areas. The light emitting display devices according to the embodiments of the present disclosure aim to solve the problems caused by the increase in the resistance of the second electrode.

The light emitting display device of the embodiments of the present disclosure may include, as shown in FIGS. 1 to 3, a substrate 100 including a plurality of light emitting portions EM (EMA, EMB, EMC) spaced apart from each other, a non-light emitting portion NEM between the plurality of light emitting portions EM (EMA, EMB, EMC), a light emitting diode ED provided on the substrate 100 so as to overlap with each of the plurality of light emitting portions EM (EMA, EMB, EMC), a first capping layer 241 and a pattern-defining layer 242 disposed on the light emitting diode ED corresponding to the plurality of light emitting portions EM (EMA, EMB, EMC), a pattern electrode 245 disposed on the non-light emitting portion NEM adjacent to a side surface of the first capping layer 241, and a second capping layer 250 covering the pattern electrode 245 and the pattern-defining layer 242.

The light emitting diode ED may include a first electrode 210 provided corresponding to each of a plurality of light emitting portions EM (EMA, EMB, EMC), an intermediate layer 220 on the first electrode, and a second electrode 230 integrally provided in the non-light emitting portion NEM between the light emitting portions EM (EMA, EMB, EMC) and the light emitting portions EM (EMA, EMB, EMC) on the intermediate layer.

The first electrode 210 is provided in each light emitting portion EM (EMA, EMB, EMC). Therefore, the first electrode 210 may be provided according to the number of light emitting portions EM (EMA, EMB, EMC) provided on the substrate 100. The first electrode 210 may be disposed to have a relatively larger surface area than the area of the light emitting portion EM (EMA, EMB, EMC) and may overlap with the bank 150 in an edge area outside the light emitting portion EM (EMA, EMB, EMC). The first electrode 210 may be disposed to cover the upper edge surface of the first electrode 210 of the bank 150.

The first electrode 210 may include, for example, a metal material having high reflectivity or a transparent electrode. For example, the first electrode 210 may be formed of a single layer structure of a transparent conductive film such as ITO (indium tin oxide), IZO (indium zinc oxide), TO (tin oxide), or ITZO (indium tin zinc oxide), a multilayer structure such as a stacked structure of aluminum (Al) and titanium (Ti) (Ti/Al/Ti), a stacked structure of aluminum (Al) and ITO (ITO/Al/ITO), an APC (Ag/Pd/Cu) alloy, a stacked structure of an APC alloy and ITO (ITO/APC/ITO), a stacked structure of silver (Ag) and molybdenum/titanium alloy (Ag/MoTi), or may include a single layer structure formed of one material selected from silver (Ag), aluminum (Al), molybdenum (Mo), gold (Au), magnesium (Mg), calcium (Ca), and barium (Ba), or an alloy of two or more thereof. When the first electrode 210 includes a reflective electrode, light may be emitted through the second electrode 230 facing the first electrode 210 and the first and second capping layers 241 and 250.

The second electrode 230 may include a transparent electrode or a thin reflective-transmissive electrode that may transmit light to allow the light produced by the intermediate layer 220 to transmit through the second electrode 230. The transparent electrode may, for example, include a transparent metal material (TCO, a transparent conductive material) such as ITO (indium tin oxide) and IZO (indium zinc oxide). The reflective-transmissive electrode may include a semi-transmissive metal material such as magnesium (Mg), silver (Ag), or an alloy of magnesium (Mg) and silver (Ag). When the second electrode 230 includes a reflective-transmissive metal material, luminous efficacy may be increased by the microcavity effect. When the second electrode 230 includes a reflective-transmissive metal material, it may have a sufficiently small thickness to allow light to pass therethrough. The thickness of the second electrode 230 may be 50 Å to 200 Å. More preferably, in consideration of the light emission characteristics and the transmission characteristics due to the microcavity effect in the light emitting portion EM (EMA, EMB, EMC), the thickness of the second electrode 230 may be 120 Å to 140 Å.

As shown in FIG. 4A, the second electrode 230 may be integrally provided in the entire light emitting portions EM (EMA, EMB, EMC) and the non-light emitting portion NEM between the light emitting portions in the sub-pixels. The second electrode 230 may be formed by depositing a second electrode-forming material using a common mask having an open area in the entire display area AA.

As shown in FIG. 4B, a first capping layer 241 and a first pattern-defining layer 242 are sequentially provided on the light emitting portions EM (EMA, EMB, EMC) on the second electrode 230.

The first capping layer 241 and the first pattern-defining layer 242 may be formed using the same mask and may be formed to a size larger than the light emitting portion EM (EMA, EMB, EMC). In some cases, the first capping layer 241 and the first pattern-defining layer 242 may partially overlap with the bank 150.

The first capping layer 241 may be an organic capping layer containing an organic material, or a composite capping layer containing an organic material and an inorganic material. In addition, the first capping layer 241 may have a lower refractive index than the organic material of the intermediate layer 220 constituting the light emitting diode ED.

The first capping layer 241 may, for example, include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may be optionally substituted with a substituent including O, N, S, Se, Si, F, Cl, Br, I, or any combination thereof.

The light emitting display device of the embodiments of the present disclosure may have a pattern electrode 245 provided on at least a non-light emitting portion NEM of an upper surface of the second electrode 230 to reduce the resistance of the second electrode 230. The pattern electrode 245 may be disposed in a smaller area than the second electrode 230, but may include a metal having higher conductivity than the component constituting the second electrode 230, thereby reducing the resistance of the second electrode 230 at the contact portion. For example, the pattern electrode 245 may include copper, silver, aluminum, gold, tungsten, or an alloy of at least one thereof.

The pattern electrode 245 may be disposed in a non-light emitting portion NEM and may include a metal having high conductivity but not transparency.

The pattern electrode 245 may have a thickness smaller than the first capping layer 241 adjacent to the side and may not contact the side of the pattern-defining layer 242. Therefore, after formation, the pattern electrode 245 has excellent adhesion to the first capping layer 241 and the second capping layer 250 on the upper side, and avoids peeling therebetween.

As shown in FIG. 4B, the pattern electrode 245 is formed after the laminated structure of the first capping layer 241 and the pattern-defining layer 242 provided on the light emitting portion EM (EMA, EMB, EMC) is formed, and, as shown in FIG. 4C, without a separate mask, the region of the pattern electrode 245 is defined by the region where the pattern-defining layer 242 is not formed. This utilizes the nucleation suppression property of the pattern-defining layer 242 and the low affinity for the conductive material.

The pattern electrode 245 may reduce the resistance of the second electrode 230 that is electrically connected to the second electrode 230 and may serve as a cathode CAT.

The pattern electrode 245 may have higher conductivity than the second electrode 230. In some cases, the pattern electrode 245 may have conductivity equal to or lower than the second electrode 230. Although the pattern electrode 245 has conductivity equal to or lower than the second electrode 230, the cathode CAT formed by laminating the second electrode 230 and the pattern electrode 245 in the non-light emitting portion NEM may be thinner than the light emitting portion EM and may reduce the resistance of the second electrode 230 of the non-light emitting portion NEM.

The pattern electrode 245 may be thinner than the second electrode 230. Alternatively, the pattern electrode 245 may have a thickness equal to or greater than the second electrode 230. Although the pattern electrode 245 has a thickness less than or equal to the second electrode 230, the cathode CAT formed by laminating the second electrode 230 and the pattern electrode 245 in the non-light emitting portion NEM has a thickness greater than the light emitting portion EM, and thus reduce the resistance of the second electrode 230 of the non-light emitting portion NEM.

The pattern-defining layer 242 may contain an organic material including an organic material and an organic polymer, and may contain a polycyclic aromatic compound containing a heteroatom such as N (nitrogen), S (sulfur), O (oxygen), phosphorus (P), or aluminum (Al), and at least one organic molecule. The polycyclic aromatic compound may contain an organic molecule including a core moiety and at least one terminal moiety bonded to the core moiety. For example, the pattern-defining layer 242 may contain 3-(4-biphenyl)-4-phenyl-5-tert-butylphenyl-1,2,4-triazole (TAZ), bis(2-methyl-8-quinolinato)-4-phenylphenolate-aluminum (BA1q), 2-(4-(9,10-di(naphthalen-2-yl) anthracen-2-yl)phenyl)-1-phenyl-1H-benzo-[D]imidazole, 8-hydroxyquinoline lithium (Liq), and N (diphenyl-4-yl) 9,9-dimethyl-N-(4 (9-phenyl-9H-carbazol-3-yl)phenyl)-9H-fluoren-2-amine, or the like.

The pattern-defining layer 242 may suppress nucleation of the pattern electrode material on the pattern-defining layer 242 when supplying the pattern electrode material for forming the pattern electrode. Therefore, the pattern electrode material is not deposited on the surface of the first pattern-defining layer 242 through the low affinity with the first pattern-defining layer 242, but moves to another surface, so that the pattern-defining layer 242 and the other surface are selectively deposited only in the non-light emitting portion NEM to form the pattern electrode 245.

Here, the pattern-defining layer 242 has a low affinity for the conductive material and thus has a surface on which the deposition of the pattern electrode 245 formed of a conductive material is suppressed. For example, the surface fixation probability of the conductive material of the pattern-defining layer 242 may be measured by depositing the amount of conductive material required to form a closed-packed layer having an average thickness of 1 nm on the surface of the pattern-defining layer. The probability of the conductive material sticking to the surface of the pattern-defining layer 242 is at most 0.3 (or 30%) and at least 0.0008 (or 0.08%). This means that, after deposition of the pattern electrode material, during the nucleation and growth process, the conductive pattern electrode material is repelled or detached from the surface of the pattern-defining layer 242 and evaporates or flows to another surface to be deposited on the surface at a different location from the region of the pattern-defining layer 242, thereby forming a pattern electrode 245 having an inverted shape with the pattern-defining layer 242, as shown in FIG. 4C.

Meanwhile, since the pattern electrode 245 whose area is defined by the pattern-defining layer 242 has a thickness smaller than the thickness of the first capping layer 241, it does not directly contact the side of the pattern-defining layer 242 after formation, thus solving the problem of the deterioration of the adhesion that occurs when it has a contact surface with the pattern-defining layer 242 and the problem of the contact surface between the pattern-defining layer and the conductive material becoming an out-gas passage for foreign substances in the panel.

After the pattern electrode 245 is formed, a second capping layer 250 covers each of the pattern electrode 245 and the pattern-defining layer 242.

The second capping layer 250 may contain an inorganic material and may contain a material having a higher refractive index than the first capping layer 241 and the pattern-defining layer 242.

The second capping layer 250 may include, for example, one of a silicon oxide film, a silicon nitride film, or a silicon oxynitride film.

The second capping layer 250 may contain an inorganic material having low reflectivity and may contain silicon oxide, a metal or metal oxide, or a metal fluoride. For example, when the second capping layer 250 contains a metal, it may contain ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), silver (Ag), magnesium (Mg), gold (Au), copper (Cu), calcium (Ca), or a combination thereof. When the second capping layer 250 contains a metal oxide or metal fluoride, it may include SiO₂, TiO₂, ZrO₂, Ta₂O₅, HfO₂, Al₂O₃, ZnO, Y₂O₃, BeO, MgO, PbO₂, WO3, SiNₓ, LiF, CaF₂, MgF₂, CdS, or a combination thereof.

Referring to FIG. 3, the micro-cavity effect is doubled at the interface between the second electrode 230 and the first capping layer 241 in the light emitting portion EM, thereby increasing the front luminous efficacy in the light emitting portion EM. In addition, since the first capping layer 241 is deposited before the pattern-defining layer 242, the second electrode 230, which is deposited thinner than the first capping layer 241, does not directly contact the pattern-defining layer 242, so that the side surface of the pattern-defining layer 242 having low affinity for conductive materials and nucleation inhibition ability, and the pattern electrode 245 do not come into contact, and thus the adhesion of the pattern electrode 245 may be stabilized both on the surface and the side surface.

After the pattern electrode 245 is formed, the second capping layer 250 is deposited in common in the light emitting portion EM and the non-light emitting portion NEM. In the light emitting portion EM, the pattern-defining layer 242 having a lower refractive index contacts the second capping layer 250 having a higher refractive index, thus causing a refractive effect at the interface, enhancing the micro-cavity effect and increasing the luminous efficacy.

As shown in FIG. 3, a thin film transistor array 500 is provided between the substrate 100 and the first electrode 210 of the light emitting diode ED and will be described in detail with reference to FIG. 4.

As shown in FIG. 4, the substrate 100 supports and protects the components disposed thereon. The substrate 100 may be transparent and flexible. The substrate 100 may be formed of, for example, a glass or plastic material.

In one embodiment of the present disclosure, the substrate 100 may include multiple layers and may, for example, include an interlayer inorganic film disposed between different flexible substrates.

FIG. 5 illustrates an example in which a blue light emitting portion BEM, a green light emitting portion GEM, and a red light emitting portion REM are disposed on the substrate 100 with a non-light emitting portion NEM therebetween, according to an embodiment.

In one embodiment of the present disclosure, the substrate 100 includes light emitting portions BEML, GEML, or REML spaced apart from each other in a display area AA and a non-light emitting portion NEM.

The transistor TFT shown in FIG. 5 may be one of the first and second transistors T1 and T2 shown in FIG. 2.

The transistor TFT provided on the substrate 100 may include, for example, an active layer 120, a gate electrode 133 overlapping with the active layer 120 with a gate insulating film 131 interposed therebetween, and a first source-drain electrode 141 and a second source-drain electrode 143 connected to both sides of the active layer 120. The active layer 120 may include a semiconductor material. The semiconductor material may include a silicon-based semiconductor material or an oxide-based semiconductor material.

A light-shielding pattern 110 may be further provided on the lower side of the transistor TFT on the substrate 100, specifically, on the lower side of the active layer 120. The light-shielding pattern 110 may prevent transmission of light to the transistor TFT due to light from the lower side of the substrate 100, thereby preventing abnormal phenomena of the active layer 120, such as generation of photocurrent.

A first insulating film 101 may be provided between the light-shielding pattern 110 on the substrate 100 and the active layer 120. The first insulating film 101 may function as a buffer layer. The first insulating film 101 may function to prevent impurities contained in the substrate 100 from being transmitted to the active layer 120 and planarize the formation surface of the active layer 120. The first insulating film 101 may cover the light-shielding pattern 110. The first insulating film 101 may protect structures on the substrate 100 that are vulnerable to moisture penetration from moisture penetrating through the substrate 100 and planarize the surface of the substrate 100.

In some cases, one or more insulating films may be provided between the light-shielding pattern 110 and the substrate 100 and function to prevent impurities from penetrating the upper array configuration from the substrate 100 and to protect the array configuration on the substrate 100.

The first source-drain electrode 141 or the second source-drain electrode 143 may be connected to the light-shielding pattern 110 in addition to being connected to the active layer 120 to stabilize the potential of the light-shielding pattern 110.

A second insulating film 102 may be provided between the gate electrode 133 and the first and second source-drain electrodes 141 and 143 for interlayer insulation. In the illustrated example, an example in which a single interlayer insulating film is provided is shown, but the present disclosure is not limited thereto. For example, multiple insulating films of different materials may be provided between the gate electrode 133, and the first and second source/drain electrodes 141 and 143.

At least one electrode of the transistor TFT and one of the electrodes of the storage capacitor Cs may be disposed on the same layer.

Meanwhile, the light-shielding pattern 110, the gate electrode 133, and the first and second source-drain electrodes 141 and 143 may each include aluminum (Al), titanium (Ti), copper (Cu), chromium (Cr), molybdenum (Mo), or tungsten (W).

A plurality of transistors TFTs may be provided in the subpixel, and some of the plurality of transistors may function as switching transistors and others as driving transistors. For different functions, the switching transistors and the driving transistors may have different stacking structures or different widths and/or lengths of the active layer channels.

For example, when the transistor TFT shown in FIG. 5 is an oxide transistor including an oxide semiconductor in the active layer 120, a crystalline transistor containing crystalline silicon as an active layer may be further provided between the substrate 100 and the first insulating film 101. The crystal transistor may be included in the sub-pixel, and in some cases, may be included as a part of the gate driving unit in the non-display area NA.

The thin film transistor TFT may be covered, and a third insulating film 103 and a fourth insulating film 104 may be provided for protection.

The first to third insulating films 101, 102, and 103 and the gate insulating film 131 may each include an inorganic insulating film, such as a silicon oxide (SiOₓ) film, a silicon nitride (SiNₓ) film, a silicon oxynitride (SiOₓN_{y}) film, or a multilayer-film in which one or more of these films are laminated.

The fourth insulating film 104 may be provided as an organic film to protect the transistor TFT and alleviate a step caused by the transistor TFT.

The fourth insulating film 104 may contain an organic material. The organic material may contain at least one of an acrylic resin, a phenolic resin, a polyimide resin, an unsaturated polyester resin, a polyamide resin, benzocyclobutene, a polyphenylene resin, or a polyphenylene sulfide resin.

A contact hole may be provided on a part of the upper portion of the second source-drain electrode 143 through the third and fourth insulating films 103 and 104, and may be connected to the first electrode 210 of the light emitting diode ED and the second source-drain electrode 143. As a result, the light emitting diode ED may be connected to the transistor TFT of the pixel circuit.

Here, the configuration between the upper surface of the substrate 100 and the first electrode 210 is referred to as a “thin film transistor array 500” shown in FIG. 3.

Between the substrate 100 and the first electrode 210, in addition to the first to fourth insulating films 101, 102, 103, and 104, and the thin film transistors described above, various functional organic films or inorganic films and thin film transistors and storage capacitors having different stack configurations may be further provided.

The light emitting diode ED includes a first electrode 210, an intermediate layer 220, and a second electrode 230 disposed in each of the light emitting portions BEM, GEM, and REM.

The first electrode 210 may function as an anode. The first electrode 210 may pass through the fourth insulating film 104 and be connected to the transistor TFT. Unlike the illustrated example, a connection electrode may be further provided between the second source/drain electrode 143 and the third insulating film 103, and the first electrode 210 may contact the connection electrode.

The first electrode 210 may, for example, contain a metal material having high reflectivity. For example, the first electrode 210 may be formed as a multilayer structure such as a stacked structure of aluminum (Al) and titanium (Ti) (Ti/Al/Ti), a stacked structure of aluminum (Al) and ITO (ITO/Al/ITO), an APC (Ag/Pd/Cu) alloy, a stacked structure of an APC alloy and ITO (ITO/APC/ITO), a stacked structure of silver (Ag) and molybdenum/titanium alloy (Ag/MoTi), or may include a single layer structure formed of one material selected from silver (Ag), aluminum (Al), molybdenum (Mo), gold (Au), magnesium (Mg), calcium (Ca), and barium (Ba), or an alloy of two or more. The first electrode 210 may be referred to as a “reflective electrode”.

An intermediate layer 220 is provided on the first electrode 210. The intermediate layer 220 may include a first common layer CML1 including a hole injection layer and a hole transport layer, organic light emitting layers BEML, GEML, and REML, and a second common layer CML2 including an electron transport layer and an electron injection layer.

The edge of the first electrode 210 may overlap with the bank 150. The area of the first electrode 210 exposed from the bank 150 may be a light emitting portion BEML, GEML, or REML. The bank 150 may include a light-shielding organic material including a transparent resin or a black pigment.

When voltage is applied to the first electrode 210 and the second electrode 230, holes and electrons move to the organic light emitting layer through the hole injection layer and the hole transport layer, and the electron injection layer and the electron transport layer, respectively, and in the organic light emitting layer, holes and electrons combine with each other to form excitons, and the excitons fall from an excited state to a ground state, thereby resulting in light emission.

When the intermediate layer 220 includes a plurality of layers, each or at least one of the plurality of layers of the intermediate layer 220 may be provided in common throughout the entire display area AA. In some cases, one or more of the plurality layers of the intermediate layer 220 may be selectively provided in the light emitting portions BEM, GEM, or REM. The light emitting diode ED may have a tandem configuration in which the intermediate layer 220 is configured as a unit stack including a light emitting layer EML, a hole-transport common layer CML1 related to hole transport on the lower side of the light emitting layer, and an electron-transport common layer CML2 related to electron transport on the upper side of the light emitting layer, and a plurality of unit stacks are provided between the first and second electrodes 210 and 230, and a charge generation layer is provided between the plurality of unit stacks. In the tandem configuration, each layer including the charge generation layer of the intermediate layer 220 may be a common layer disposed on the entire surface of the display area AA.

The intermediate layer 220 may include at least one red light emitting layer REML that emits red light, a green light emitting layer GEML that emits green light, and a blue light emitting layer BEML that emits blue light. The red light emitting layer REML, the green light emitting layer GEML, and the blue light emitting layer BEML may be disposed on the first electrode 210 for each sub-pixel SP. The red light emitting layer REML may be disposed in a pattern for the red sub-pixel, the green light emitting layer GEML may be disposed in a pattern for the green sub-pixel, and the blue light emitting layer BEML may be disposed in a pattern for the blue sub-pixel, but is not necessarily limited thereto, and at least two or more organic light emitting layers among the red light emitting layer, the green light emitting layer, and the blue light emitting layer may be laminated and disposed for one sub-pixel SP.

The intermediate layer 220 may be a white light emitting layer that emits white light. In this case, the white light emitting layer may be formed as a common layer that is integrally disposed in a plurality of sub-pixels having a configuration in which a plurality of unit stacks are laminated.

The second electrode 230 may be a common layer that is commonly disposed in the sub-pixels SP and applies the same voltage. For this purpose, the second electrode 230 may be disposed to extend from the display area AA to a part of the non-display area NA.

The second electrode 230 may include a transparent electrode or a reflective-transmissive electrode. The second electrode 230 may include a transparent metal material (TCO, a transparent conductive material) that transmits light, such as ITO (indium tin oxide) and IZO (indium zinc oxide), or a semi-transmissive metal material such as magnesium (Mg), silver (Ag), or an alloy of magnesium (Mg) and silver (Ag). When the second electrode 230 includes a semi-transmissive metal material, the luminous efficacy may be increased by the micro-cavity effect. When the second electrode 230 includes a semi-transmissive metal material, it may have a sufficiently small thickness to allow light to pass therethrough.

The light emitting display device of the embodiments of the present disclosure may reduce the resistance of the second electrode 230 formed over a large area by selectively providing a highly conductive pattern electrode 245 on a part of a non-light emitting portion NEM on top of the second electrode 230.

A first capping layer 241 and a pattern-defining layer 242 are laminated on the light emitting layers BEML, GEML, or REML adjacent to the pattern electrode 245, and the pattern electrode 245 is provided in an area where the pattern-defining layer 242 is not provided.

In addition, a second capping layer 250 covers the pattern-defining layer 242 and the pattern electrode 245.

The first and second capping layers 241 and 250 provided on the light emitting layers BEML, GEML, and REML may improve the micro-cavity characteristics at each interface, thereby improving the light emitting characteristics.

The first electrode 210 may include a reflective electrode to prevent light generated in the intermediate layer 220 from being transmitted to the light-shielding component below the first electrode 210. The light generated in the intermediate layer 220 may resonate between the second electrode 230 and the first electrode 210, and may ultimately be emitted upward through the second electrode 230. Since the first electrode 210 includes a reflective component, even if it overlaps with the wiring and the transistor TFT, the light emitting portion BEML, GEML, or REML may recognize the light emitted from the light emitting diode ED without affecting the disposition.

The pattern electrode 245 may have an opening corresponding to each of the plurality of light emitting portions BEM, GEM, or REM. The opening of the pattern electrode 245 may be larger than the light emitting portions BEM, GEM, or REM.

As shown in FIG. 6, the pattern-defining layer may contain a material having a low refractive index of approximately 1.38 to 1.41 in the visible light wavelength range. In addition, since the absorption coefficient of the pattern-defining layer is almost 0 in the visible light wavelength range, the pattern-defining layer only contributes to the formation of the pattern electrode 245 even if it is provided in the light emitting portion, and does not absorb light by itself and thus does not affect the light emission characteristics of the light emitting portion.

The pattern-defining layer 242 may contain an organic material having a lower refractive index than the second capping layer 250.

The second capping layer 250 may be formed of an inorganic material having a relatively higher refractive index than the pattern-defining layer 242 and the first capping layer 241.

The second capping layer 250 may have a higher refractive index than the first capping layer 241.

As shown in FIG. 5, the entire side surface of the pattern electrode 245 may contact a portion of the side surface of the first capping layer 241. Therefore, the pattern electrode 245 may avoid direct contact with the pattern-defining layer 242 located on the first capping layer 241, thereby stabilizing the adhesive properties of the side surface and preventing the deterioration in which the contact surface becomes a path for outgas.

The first capping layer 241 may contain an organic material and the second capping layer 250 may contain an inorganic material.

The lower surface of the pattern electrode 245 may contact the upper surface of the second electrode 230.

The second electrode 230 and the pattern electrode 245 that contact each other electrically function together as a cathode CAT and may reduce the resistance of the cathode CAT disposed throughout the display area AA.

For example, it is assumed that the surface resistance of the second electrode 230 is A, the surface resistance of the pattern electrode is B, and the aperture ratio of the light emitting portion that does not overlap with the pattern electrode is C %.

In this case, the surface resistance is C*A % in the light emitting portion and (1−C)*((A*B)/(A+B)) % in the non-light emitting portion, and the surface resistance of the panel is the sum of the surface resistances of the light emitting portion and the non-light emitting portion.

For example, the surface resistance of the panel calculated under the assumption that the aperture ratio C % of the light emitting portion is 38%, the surface resistance A of the second electrode 230 is 7Ω/□, and the surface resistance B of the pattern electrode 245 is 6Ω/□, is 4.66Ω/□, which is approximately 33.4% lower than 7Ω/□ that is the surface resistance of the second electrode 230.

That is, the light emitting display device according to the embodiment of the present disclosure may reduce the surface resistance of the cathode by 33.4% compared to a single second electrode by electrically connecting the second electrode functioning as a cathode to the pattern electrode, thus having an advantage of greatly reducing the surface resistance within a large-area panel.

The second electrode 230 includes a reflective-transmissive electrode and the thickness of the second electrode 230 may be less than that of the first capping layer 241.

The second electrode 230 may include a reflective-transmissive electrode and the pattern electrode 245 may be more conductive and thinner than the second electrode 230.

As shown in FIG. 5, a bank 150 covering the edge of the first electrode 210 disposed in the non-light emitting portion NEM is included. The pattern electrode 245 may overlap with the bank 150.

As shown in FIG. 5, the pattern electrode 245 may have a smaller planar area than that of the bank 150. In addition, the bank 150 may have a lower surface parallel to the surface of the substrate 100 in cross-section, two tapers inclined at a predetermined angle with respect to the lower surface, and an upper surface disposed between the two tapers and parallel to the surface of the substrate, and the pattern electrode 245 may be disposed within the upper surface of the bank 150.

Meanwhile, an end line MPLE of the pattern electrode 245 may be disposed on the upper surface of the bank 150, and the end line MPLE of the pattern electrode 245 may be disposed on the same vertical line as the end line of the pattern-defining layer 242 in cross-section.

Meanwhile, an encapsulation layer may be provided on the pattern-defining diode ED to protect and encapsulate the light emitting diode.

The encapsulation layer may be provided as a single film or as multiple films. When the encapsulation layer is provided as multiple films, for example, at least one organic encapsulation layer and at least one organic encapsulation layer may be alternately disposed. The uppermost film and the lowermost film of the encapsulation layer are preferably inorganic encapsulation layers, to prevent external air such as moisture from penetrating from the outside.

The encapsulation layer planarizes the surface curvature of the pattern-defining diode ED. Therefore, a shielding film including a touch sensor or a light-shielding layer and a color converter may be further provided on the encapsulation layer.

Hereinafter, the results of measurement of the luminous efficacy in a structure having a single capping layer applied to the light emitting portion and a structure having the thicknesses of the pattern-defining layer and the second capping layer according to the embodiment of the present disclosure when the thicknesses of the pattern-defining layer and the second capping layer are adjusted will be described.

TABLE 1

| | Pattern- | Second | |
|---|---|---|---|
| | defining layer | capping layer (Y) | Cd/A/CIEy |
| Item | (X) [nm] | [nm] | (%) |
| EX1 | Absence | 500 | 100 |
| EX2 | 200 | 300 | 100.5 |
| EX3 | 300 | 200 | 100.5 |
| EX4 | 400 | 100 | 100.5 |

Experimental Example 1 EX1 was formed by sequentially laminating the first capping layer and the second capping layer on the second electrode of FIG. 3 in the light emitting portion. The thickness of the first capping layer was 100 nm and the thickness of the second capping layer was 500 nm.

Experimental Example 2 EX2 has the configuration of FIG. 3, and a 200 nm thick pattern-defining layer and a 300 nm thick second capping layer were sequentially formed on the 100 nm thick first capping layer.

Experimental Example 3 EX3 has the configuration of FIG. 3, and a 300 nm thick pattern-defining layer and a 200 nm thick second capping layer were sequentially formed on the 100 nm thick first capping layer.

Experimental Example 4 EX4 has the configuration of FIG. 3, and a 400 nm thick pattern-defining layer and a 100 nm thick second capping layer are sequentially formed on a 100 nm thick first capping layer.

The luminous efficacy is measured by the blue index luminous efficacy in each experimental example and is obtained by dividing each evaluated luminance by the y color coordinate of blue.

It can be seen that the blue index luminous efficacy is improved in all of Experimental Examples 2, 3 and 4 EX2, EX3, and EX4, compared to Experimental Example 1 EX1.

The light emitting display device according to one embodiment of the present disclosure may reduce the resistance of the second electrode and prevent luminance unevenness caused by voltage unevenness of the second electrode formed over a large area by disposing a highly conductive pattern electrode on the non-light emitting portion of the second electrode provided as a common electrode.

According to one embodiment of the present disclosure, a light emitting display device is manufactured by first forming a first capping layer and a pattern-defining layer in a light emitting portion on a second electrode, and then disposing a highly conductive pattern electrode in a region different from the pattern-defining layer using the nucleation inhibition force of a conductive material of the pattern-defining layer and the non-affinity of the conductive material. Therefore, there is no temperature limitation of the mask in a situation where a high temperature is required during deposition because a separate mask does not need to be used when forming the pattern electrode, and the adhesion characteristics of the pattern electrode are stabilized and the reliability of the device is improved because the pattern electrode is thinner than the first capping layer and thus the pattern electrode does not directly contact the pattern-defining layer.

According to an embodiment of the present disclosure, the light emitting display device has a configuration in which a second electrode and a first capping layer directly contact the light emitting portion, thus controlling the refractive characteristics at the interface and improving the micro-cavity characteristics.

According to an embodiment of the present disclosure, a light emitting display device has a second capping layer that is commonly disposed on top of a pattern electrode and a pattern-defining layer, and the second capping layer contacts the pattern-defining layer with a higher refractive index than the pattern-defining layer in the light emitting portion, thus causing a refractive effect at the interface and enhancing the microcavity effect and increasing the light emission efficiency.

The light emitting display device according to an embodiment of the present disclosure may prevent conductive materials around the pattern-defining layer from directly contacting each other, thereby preventing the side surface of the pattern-defining layer from being used as an out-gas path.

The light emitting display device according to an embodiment of the present disclosure is advantageous in implementing an eco-friendly device in terms of reducing the resistance of the second electrode, improving the brightness unevenness, and improving the reliability of the bonding surface of the pattern electrode, implementing process optimization, and achieving ESG (environmental/social/governance) effects.

Hereinafter, the light emitting display device of another embodiment will be described.

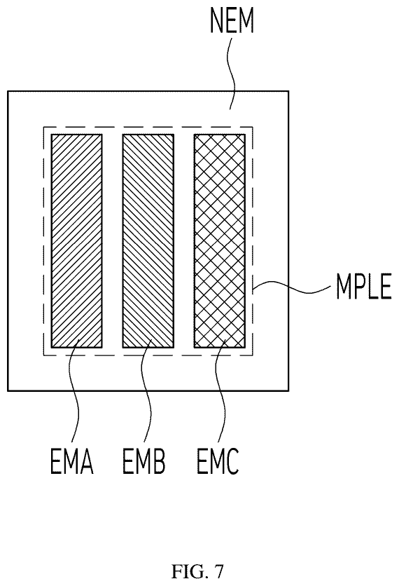

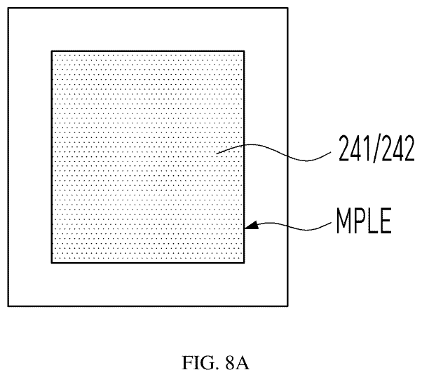

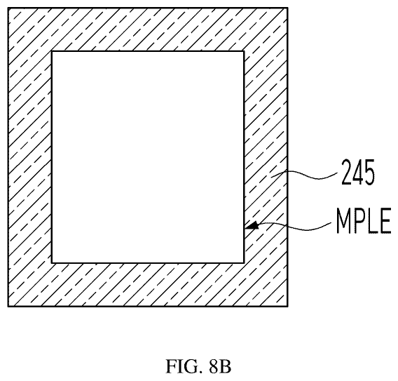

FIG. 7 is a plan view illustrating a unit pixel of a light emitting display device according to another embodiment of the present disclosure. FIG. 8A is a plan view illustrating a first capping layer and a pattern-defining layer of the unit pixel of FIG. 7. FIG. 8B is a plan view illustrating a pattern electrode of the unit pixel of FIG. 7.

The light emitting display device of FIG. 7 illustrates an example in which light emitting portions EMA, EMB, and EMC are spaced apart from each other in a stripe manner, and a non-light emitting portion NEM is disposed between the spaced areas of the light emitting portions EMA, EMB, and EMC.

Here, the light emitting portions EMA, EMB, and EMC are disposed in parallel to form a first capping layer 241 and a pattern-defining layer 242 on the second electrode 230, as shown in FIGS. 3 and 8A. The first capping layer 241 and the pattern-defining layer 242 may overlap with all of the light emitting portions EMA, EMB, and EMC, and the spaces between the light emitting portions. In this case, the first capping layer 241 and the pattern-defining layer 242 may be formed in the different light emitting portions EMA, EMB, and EMC defined as one unit.

Then, as shown in FIG. 8B, a pattern electrode 245 is formed in an area where the pattern-defining layer 242 is not formed.

In this case, the pattern electrode 245 may surround the pixels in each unit.

The light emitting display device of FIG. 7 may also have the shape of the cross-sectional structure of FIG. 3, is capable of reducing the resistance of the second electrode 230 by connecting the second electrode 230 to the pattern electrode 245, and is capable of improving the reliability of the side bonding characteristics of the pattern electrode 245 by designing the thickness of the pattern electrode 245 to be lower than that of the first capping layer 241.

The light emitting display device according to one embodiment of the present disclosure is capable of reducing the resistance of the second electrode and of preventing brightness unevenness caused by voltage unevenness of the second electrode formed over a large area because a highly conductive pattern electrode is disposed in the non-light emitting portion of the second electrode provided as a common electrode.

A light emitting display device according to one embodiment of the present disclosure may comprise a plurality of light emitting portions spaced from each other and a non-light emitting portion between the light emitting portions, a light emitting diode on the substrate, the light emitting diode overlapping with the plurality of light emitting portions, a first capping layer and a pattern-defining layer on the light emitting diode at the light emitting portions, a pattern electrode adjacent to a side surface of the first capping layer at the non-light emitting portion and a second capping layer covering the pattern electrode and the pattern-defining layer.

In a light emitting display device according to one embodiment of the present disclosure, the pattern electrode may contact a side surface of the first capping layer at the non-light emitting portion surrounding each of the plurality of light emitting portions.

In a light emitting display device according to one embodiment of the present disclosure, the pattern electrode may have a plurality of openings corresponding to the plurality of light emitting portions.

In a light emitting display device according to one embodiment of the present disclosure, the pattern-defining layer may comprise an organic material having a lower refractive index than the second capping layer.

In a light emitting display device according to one embodiment of the present disclosure, the second capping layer may have a higher refractive index than the first capping layer.

In a light emitting display device according to one embodiment of the present disclosure, an entire side surface of the pattern electrode may contact a part of the side surface of the first capping layer.

In a light emitting display device according to one embodiment of the present disclosure, the first capping layer may comprise an organic material and the second capping layer may comprise an inorganic material.

In a light emitting display device according to one embodiment of the present disclosure, the light emitting diode may comprise a plurality of first electrodes corresponding to the plurality of light emitting portions, an intermediate layer on the plurality of first electrodes and a second electrode on the intermediate layer, the second electrode integrally disposed at the plurality of light emitting portions and the non-light emitting portion between the light emitting portions.

In a light emitting display device according to one embodiment of the present disclosure, a lower surface of the pattern electrode may contact an upper surface of the second electrode.

In a light emitting display device according to one embodiment of the present disclosure, the second electrode may comprise a reflective transmissive electrode, and the second electrode may be thinner than the first capping layer.

In a light emitting display device according to one embodiment of the present disclosure, the second electrode may comprise a reflective transmissive electrode. The pattern electrode may be more conductive than the second electrode.

A light emitting display device according to one embodiment of the present disclosure may further comprise a bank covering edges of the plurality of first electrode at the non-light emitting portion. The pattern electrode may overlap with the bank.

In a light emitting display device according to one embodiment of the present disclosure, the pattern electrode may have a planar area smaller than a planar area of the bank.

In a light emitting display device according to one embodiment of the present disclosure, the bank may have a lower surface parallel to the surface of the substrate, two tapers inclined at a predetermined angle with the lower surface, and an upper surface disposed between the two tapers and parallel to the surface of the substrate in a cross-section. The pattern electrode may be disposed within the upper surface of the bank.

The effects of the light emitting display device according to the present disclosure are as follows.

The light emitting display device according to one embodiment of the present disclosure is capable of reducing the resistance of the second electrode and of preventing brightness unevenness caused by voltage unevenness of the second electrode formed over a large area because a highly conductive pattern electrode is disposed in the non-light emitting portion of the second electrode provided as a common electrode.

According to one embodiment of the present disclosure, a light emitting display device is manufactured by first forming a first capping layer and a pattern-defining layer in a light emitting portion on a second electrode, and then disposing a highly conductive pattern electrode in a region different from the pattern-defining layer using the nucleation inhibition force of a conductive material of the pattern-defining layer and the non-affinity of the conductive material. Therefore, there is no temperature limitation of the mask in a situation where a high temperature is required during deposition because a separate mask does not need to be used when forming the pattern electrode, and the adhesion characteristics of the pattern electrode are stabilized and the reliability of the device is improved because the pattern electrode is thinner than the first capping layer and thus the pattern electrode does not directly contact the pattern-defining layer.

According to an embodiment of the present disclosure, the light emitting display device has a configuration in which a second electrode and a first capping layer directly contact the light emitting portion, thus controlling the refractive characteristics at the interface and improving the micro-cavity characteristics.

According to an embodiment of the present disclosure, a light emitting display device has a second capping layer that is commonly disposed on top of a pattern electrode and a pattern-defining layer, and the second capping layer contacts the pattern-defining layer with a higher refractive index than the pattern-defining layer in the light emitting portion, thus causing a refractive effect at the interface and enhancing the microcavity effect and increasing the light emission efficiency.

The light emitting display device according to an embodiment of the present disclosure may prevent conductive materials around the pattern-defining layer from directly contacting each other, thereby preventing the side surface of the pattern-defining layer from being used as an out-gas path.

The light emitting display device according to an embodiment of the present disclosure is advantageous in implementing an eco-friendly device in terms of reducing the resistance of the second electrode, improving the brightness unevenness, and improving the reliability of the bonding surface of the pattern electrode, implementing process optimization, and achieving ESG (environmental/social/governance) effects.

It will be apparent to those skilled in the art that various modifications and variations may be made in the present disclosure without departing from the spirit or scope of the inventions. Thus, it is intended that the present disclosure covers the modifications and variations of this invention provided they come within the scope of the appended claims and their equivalents.

What is claimed is:

1. A light emitting display device comprising:
a plurality of light emitting portions spaced from each other and a non-light emitting portion between each of the plurality of light emitting portions;
a light emitting diode disposed on a substrate, the light emitting diode overlapping with the plurality of light emitting portions;
a first capping layer and a pattern-defining layer on the light emitting diode at the light emitting portions;
a pattern electrode adjacent to a side surface of the first capping layer at the non-light emitting portion; and
a second capping layer covering the pattern electrode and the pattern-defining layer.

2. The light emitting display device according to claim 1, wherein the pattern electrode contacts a side surface of the first capping layer at the non-light emitting portion surrounding each of the plurality of light emitting portions.

3. The light emitting display device according to claim 1, wherein the pattern electrode has a plurality of openings corresponding to the plurality of light emitting portions.

4. The light emitting display device according to claim 1, wherein the pattern-defining layer comprises an organic material having a lower refractive index than the second capping layer.

5. The light emitting display device according to claim 1, wherein the second capping layer has a higher refractive index than a refractive index of the first capping layer.

6. The light emitting display device according to claim 1, wherein an entire side surface of the pattern electrode contacts a part of the side surface of the first capping layer.

7. The light emitting display device according to claim 1, wherein:
the first capping layer comprises an organic material, and
the second capping layer comprises an inorganic material.

8. The light emitting display device according to claim 1, wherein the light emitting diode comprises:
a plurality of first electrodes corresponding to the plurality of light emitting portions;
an intermediate layer on the plurality of first electrodes; and
a second electrode on the intermediate layer, the second electrode integrally disposed at the plurality of light emitting portions and the non-light emitting portion between the light emitting portions.

9. The light emitting display device according to claim 8, wherein a lower surface of the pattern electrode contacts an upper surface of the second electrode.

10. The light emitting display device according to claim 8, wherein:
the second electrode comprises a reflective transmissive electrode, and
the second electrode is thinner than the first capping layer.

11. The light emitting display device according to claim 8, wherein:
the second electrode comprises a reflective transmissive electrode, and the pattern electrode is more conductive than the second electrode.

12. The light emitting display device according to claim 8, further comprising a bank covering edges of the plurality of first electrodes at the non-light emitting portion,
wherein the pattern electrode overlaps with the bank.

13. The light emitting display device according to claim 12, wherein the pattern electrode has a planar area that is smaller than a planar area of the bank.

14. The light emitting display device according to claim 12, wherein:
the bank has a lower surface parallel to a surface of the substrate, wherein two tapers are inclined at a predetermined angle with the lower surface, and wherein an upper surface is disposed between the two tapers and parallel to the surface of the substrate in a cross-section, and
the pattern electrode is disposed within the upper surface of the bank.
